(19) United States
(12) Patent Application Publication
(10) Pub. No.: US 2021/0026997 A1
(43) Pub. Date: Jan. 28, 2021

(54) METHOD FOR CREATING KNOWLEDGE REPRESENTATION MODEL FOR PRODUCT

(71) Applicant: GUANGDONG INSTITUTE OF INTELLIGENT MANUFACTURING, Guangzhou (CN)

(72) Inventors: Hao Qin, Guangzhou, Guangdong (CN); Qianzhou Wei, Guangzhou, Guangdong (CN); Rui Yang, Guangzhou, Guangdong (CN); Yu Zhang, Guangzhou, Guangdong (CN); Xiang Ling, Guangzhou, Guangdong (CN); Dongbo Zhang, Guangzhou, Guangdong (CN); Libin Lin, Guangzhou, Guangdong (CN); Zhi Liu, Guangzhou, Guangdong (CN); Xu Guo, Guangzhou, Guangdong (CN)

(21) Appl. No.: 16/995,786

(22) Filed: Aug. 17, 2020

Related U.S. Application Data
(63) Continuation-in-part of application No. PCT/CN2019/114922, filed on Nov. 1, 2019.

(30) Foreign Application Priority Data
Jul. 25, 2019 (CN) 201910675877.3

(51) Int. Cl. G06F 30/10; G06F 16/2458; G06Q 30/02; G06N 20/00; G06N 5/02

(52) U.S. Cl. CPC G06F 30/10; G06F 16/2465; G06K 9/6257; G06N 20/00; G06N 5/022; G06Q 30/0201

(57) ABSTRACT

A method for creating a knowledge representation model for a product includes: systematically capturing and representing knowledge and experience generated in product design and production processes, classifying the knowledge into five aspects, namely requirement, function, behavior, structure and evolution, and transforming unstructured tacit knowledge into structured knowledge in terms of know-what, know-how and know-why. Based on the knowledge representation model and knowledge bases, the present invention can be used to guide the construction of corresponding geometric model libraries, material libraries and process libraries, etc., and then to create design big data. The present invention can also be combined with an intelligent recommendation algorithm to intelligently recommend relevant data, information and knowledge based on the design engineers' working context and tasks undertaken. In addition, the present invention can be applied to knowledge management in the engineering design process, creating design big data, and then intelligently generating and optimizing design schemes.

### CROSS-REFERENCE TO RELATED APPLICATIONS

The present application is a Continuation-In-Part Application of PCT Application NO. PCT/CN2019/114922 filed on Nov. 1, 2019, which claims priority of Chinese Patent Application No. 201910675877.3 filed on Jul. 25, 2019, the contents of which are hereby incorporated by reference.

### TECHNICAL FIELD

The present invention relates to the technical field of engineering design, in particular to a method for creating a knowledge representation model for a product.

### BACKGROUND

In the process of engineering design (such as mechanical design, architectural design and electronic design), a large amount of knowledge and experience are accumulated by design engineers, which play a vital role in design decision-making. The effective capture, representation and reuse of the knowledge and experience will greatly improve the design efficiency. However, since the knowledge and experience are unstructured and often exist in the minds of design engineers, they are difficult to be represented systematically. To make the unstructured knowledge structured, it is necessary to create a knowledge representation model. The existing knowledge representation models are mainly aimed at the general computer discipline, and there is no knowledge representation model specifically oriented to the field of engineering design. The engineering design process is quite complex and requires the use of various types of data, information and knowledge, so it is necessary to build a special knowledge representation model for knowledge acquisition, representation and reuse.

### SUMMARY

In order to solve the above-mentioned problems existing in the prior art, the present invention proposes a method for creating a knowledge representation model for a product. Knowledge and experience generated in product design and production processes are systematically captured and represented, and classified into five aspects, namely requirement, function, behavior, structure and evolution. Unstructured tacit knowledge is transformed into structured knowledge in terms of know-what, know-how and know-why.

The present invention solves the above problems through the following technical solutions:

A method for creating a knowledge representation model for a product, including the following steps:

capturing text data and image data;

mining customer requirements and market requirements from the text data, and classifying and systematically representing the customer requirements and market requirements in the form of a semantic network, to establish a requirement model;

mining product information from the text data and image data, functionally decomposing the product information, dividing a main function to be achieved into sub-functions needed to achieve the main function, to establish a function model;

defining a behavior of each part of the product to establish a behavior model, the behavior being composed of various indicators to be achieved by the product;

decomposing a structure of the product into various mechanisms and components, and representing relevant geometric information of each of the mechanisms and components together to establish a structure model, the relevant geometric information being geometric information, material information or manufacture information;

recording design iteration and evolution processes of the requirement model, function model, behavior model and structure model, and capturing knowledge and experience therein, to establish an evolution model;

where the requirement model, function model, behavior model, structure model and evolution model display knowledge on a screen in a structured form, and receive selection, addition, modification, deletion or saving operations performed by a user; and

integrating the requirement model, function model, behavior model, structure model and evolution model to build a complete knowledge representation model of the product.

Further, the step of mining customer requirements and market requirements from the text data, and classifying and systematically representing the customer requirements and market requirements in the form of a semantic network to establish a requirement model includes: transforming scattered and abstract requirements into various functions to be achieved by the product, and systematically capturing and representing knowledge and experience formed in this process in the form of know-what, know-how and know-why.

Further, the step of defining a behavior of each part of the product to establish a behavior model, the behavior being composed of various indicators to be achieved by the product includes: setting an optimal indicator of each sub-function, and comparing an actually achieved indicator with the optimal indicator to iteratively improve the product design until the actual indicator reaches or approximates the optimal indicator.

Further, the step of decomposing a structure of the product into various mechanisms and components, and representing relevant geometric information of each of the mechanisms and components together to establish a structure model, the relevant geometric information being geometric information, material information or manufacture information includes: dividing the structure of the product into systems, subsystems, mechanisms and components according to the functions of the product, and capturing corresponding information in the smallest unit of components.

Further, the step of recording design iteration and evolution processes of the requirement model, function model, behavior model and structure model, and capturing knowledge and experience therein, to establish an evolution model includes: capturing the evolution process of a design scheme based on the requirement, function, behavior and structure models.

Compared with the prior art, the present invention has the following beneficial effects:

The present invention performs knowledge modeling for the capture, representation and reuse of knowledge in engineering design, to capture and reuse the knowledge and experience in the minds of design engineers to help them quickly make design decisions, thereby improving design efficiency. The present invention creates a knowledge representation model to capture the unstructured knowledge and experience of design engineers, transform the unstructured knowledge and experience into structured knowledge and experience, and systematically save them in knowledge bases. Based on the knowledge representation model and knowledge bases, the present invention can be used to guide the construction of corresponding geometric model libraries, material libraries and process libraries, etc., and then to create design big data. The present invention can also be combined with an intelligent recommendation algorithm to intelligently recommend relevant data, information and knowledge based on the design engineers' working context and tasks undertaken. The present invention can be applied to knowledge management in the engineering design process, creating design big data, and then intelligently generating and optimizing design schemes.

### BRIEF DESCRIPTION OF DRAWINGS

In order to describe the technical solutions in the embodiments of the present invention more clearly, the accompanying drawings required to describe the embodiments are briefly described below. Apparently, the accompanying drawings described below are only some examples of the present invention. Those of ordinary skill in the art may further obtain other accompanying drawings based on these accompanying drawings without inventive effort.

FIG. 1 is a structural diagram of a requirement analysis model of the present invention.

FIG. 2 is a structural diagram of a functional decomposition model the present invention.

FIG. 3 is a structural diagram of a behavior analysis model of the present invention.

FIG. 4 is a structural diagram of a structural decomposition model of the present invention.

FIG. 5 is a structural diagram of a design evolution model of the present invention.

FIG. 6 is a structural diagram of a knowledge representation model of the present invention.

FIG. 7 is a structural diagram of a system for creating a knowledge representation model according to the present invention.

Numeral references: 101 CPU, 102 network, 103 NIU, 104 I/O controller, 105 display, 106 input device, 107 system bus, 108 system memory, and 109 MSD.

### DESCRIPTION OF EMBODIMENTS

In order to make the above objectives, features and advantages of the present invention more understandable, the technical solutions of the present invention are described in detail below with reference to the accompanying drawings and specific embodiments. It should be pointed out that the described embodiments are merely a part rather than all of the embodiments of the present invention. All other embodiments obtained by a person of ordinary skill in the art based on the embodiments of the present invention without creative efforts should fall within the protection scope of the present invention.

### Embodiment

The present invention provides a method for creating a knowledge representation model, including systematically capturing and representing knowledge and experience generated in product design and production processes, classifying the knowledge into five aspects, namely requirement, function, behavior, structure and evolution, and transforming unstructured tacit knowledge into structured knowledge in terms of know-what, know-how and know-why.

1. Establish a requirement model, to classify and systematically represent customer requirements and market requirements in the form of a semantic network.

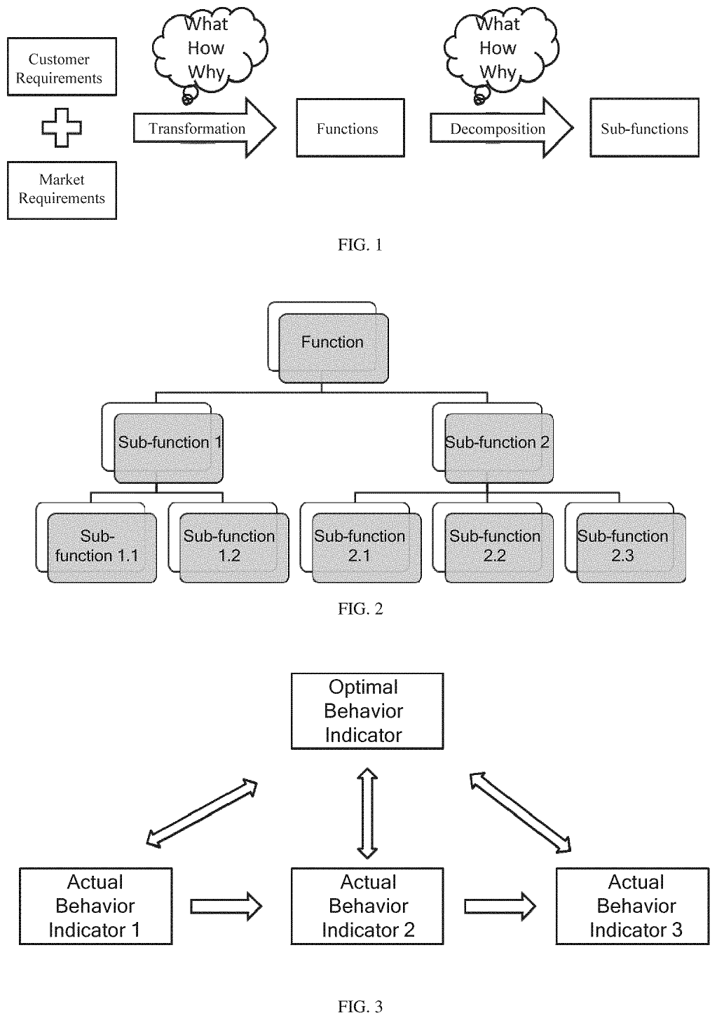

As shown in FIG. 1, a requirement model is established to classify and systematically represent customer requirements and market requirements in the form of ontology web language (OWL). First, a large amount of text data and image data related to a product are acquired by mining from Internet data, inputting by a user or photographing by a camera device. The original text data are transformed and extracted by using an information extraction tool, filtered by using a dictionary database, and re-filtered by using a text search engine, thereby obtaining accurate, keyword-labeled and structured text data information. Through the above process, the customer requirements and market requirements are accurately and completely mined, and classified and systematically represented in the form of a semantic network. In this process, the scattered and abstract requirements are transformed into various functions to be achieved by the product, and the formed knowledge and experience are systematically captured and represented in the form of know-what, know-how and know-why.

2. Establish a function model, to functionally decompose the product, divide a main function to be achieved into sub-functions needed to achieve the main function.

As shown in FIG. 2, a function model is established to functionally decompose the product, divide a main function to be achieved into sub-functions needed to achieve the main function. In addition to the text data information, corresponding image data information is also needed so as to obtain the product information. To obtain high-quality images, the image data is processed by using image processing methods that are commonly used in the art, such as overall views, computer-aided design (CAD) drawings of components decomposed in different manners and detail drawings. The images are marked and saved in a database for users to view, select and modify. Through functional decomposition, the task is subdivided to better capture the knowledge and experience formed in the design analysis process.

3. Establish a behavior model, to define a behavior of each part of the product, the behavior being composed of various indicators to be achieved by the product.

As shown in FIG. 3, a behavior analysis model is established to define a behavior of each part of the product, the behavior being composed of various indicators to be achieved by the product. An optimal indicator of each sub-function is set, and an actually achieved indicator is compared with the optimal indicator to iteratively improve the product design until the actual indicator reaches or approximates the optimal indicator.

4. Establish a structure model, to decompose a structure of the product into various mechanisms and components and represent relevant geometric information of each of the mechanisms and components together, the relevant geometric information being geometric information, material information or manufacture information.

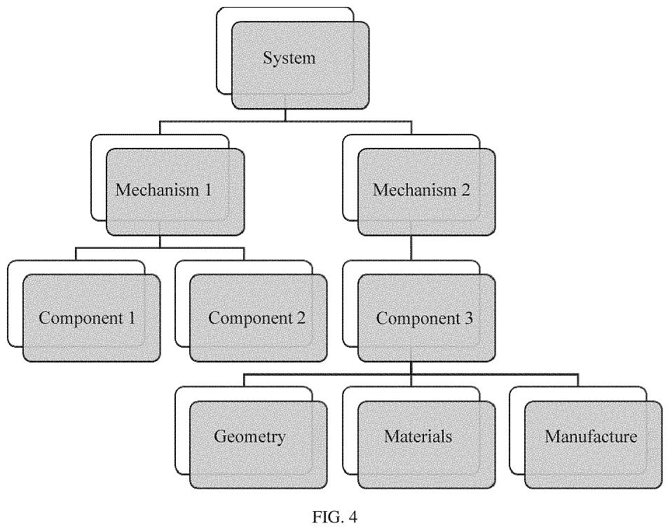

As shown in FIG. 4, a structure model is established to decompose a structure of the product into various mechanisms and components and represent relevant geometric information of each of the mechanisms and components together, the relevant geometric information being geometric information, material information or manufacture information. The structure of the product is divided into systems, subsystems, mechanisms and components according to the functions of the product, and corresponding information is captured in the smallest unit of components.

5. Establish an evolution model, to record design iteration and evolution processes of the above-mentioned models and capture knowledge and experience therein.

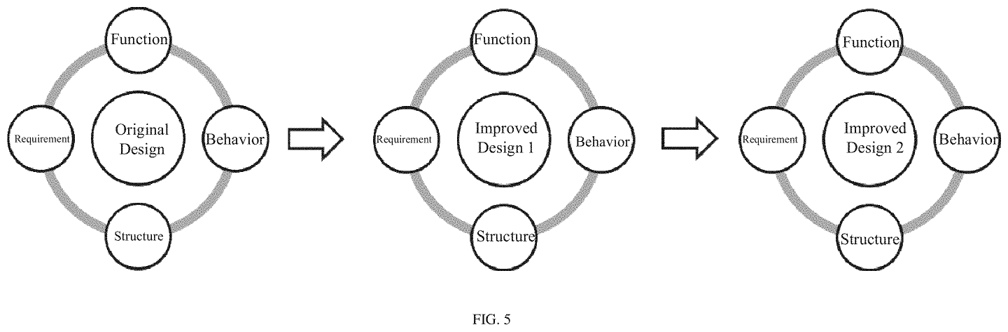

As shown in FIG. 5, an evolution model is established to record design iteration and evolution processes of these models and capture knowledge and experience therein. The evolution process of the design scheme is captured based on the requirement, function, behavior and structure models.

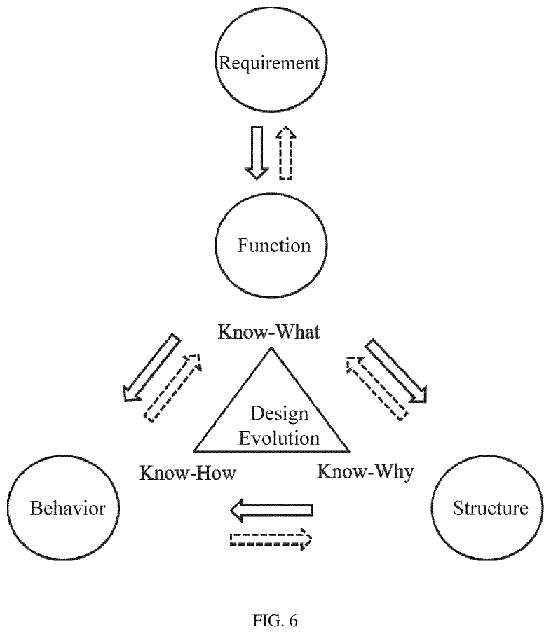

6. Integrate these 5 models to build a complete knowledge representation model of the product, as shown in FIG. 6.

The requirement model, function model, behavior model, structure model and evolution model are displayed on a screen to receive selection, addition, modification, deletion or saving operations performed by a user. During the establishment process, each model can be displayed on an on-screen interface to receive user instructions to operate, such as select, add, modify, deletion, retrieve or save. After these models are established, one or more model interfaces can be displayed according to user instructions, and operations such as selection, addition, modification, deletion, retrieval or saving can also be performed according to user instructions.

The present invention performs knowledge modeling for the capture, representation and reuse of knowledge in engineering design, to capture and reuse the knowledge and experience in the minds of design engineers to help them quickly make design decisions, thereby improving design efficiency. The present invention creates a knowledge representation model to capture the unstructured knowledge and experience of design engineers, transform the unstructured knowledge and experience into structured knowledge and experience, and systematically save them in knowledge bases. Based on the knowledge representation model and knowledge bases, the present invention can be used to guide the construction of corresponding geometric model libraries, material libraries and process libraries, etc., and then to create design big data. The present invention can also be combined with an intelligent recommendation algorithm to intelligently recommend relevant data, information and knowledge based on the design engineers' working context and tasks undertaken. The present invention can be applied to knowledge management in the engineering design process, creating design big data, and then intelligently generating and optimizing design schemes.

The present invention further provides a system for creating a knowledge representation model for a product, including a display, a communication device, a memory and a processor, where the memory is used to store data and a computer program; the processor is used to execute the computer program stored on the memory to implement the method for creating a knowledge representation model according to any of the above. The communication device includes but is not limited to a universal serial bus (USB) interface, a wireless communication interface, a corresponding USB hardware device and a wireless communication device, etc., where the wireless communication device can be a wireless fidelity (Wi-Fi) transmission device, a Bluetooth transmission device, a Zigbee transmission device or a radio frequency (RF) transmission device well known in the communication field.

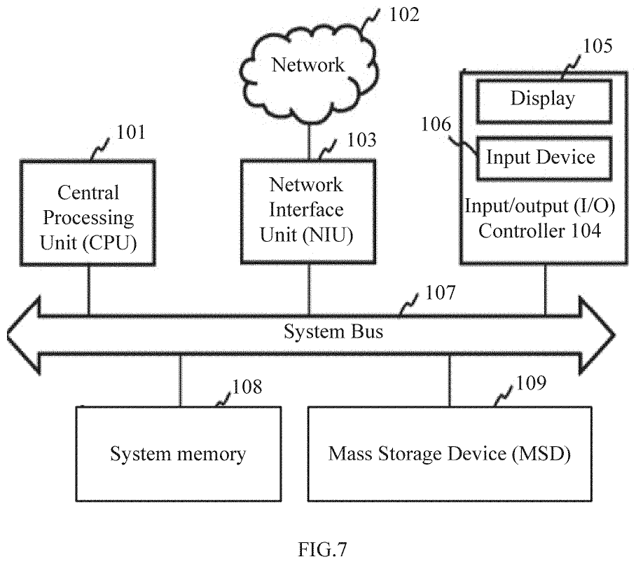

As shown in FIG. 7, specifically, the communication device of the system includes a NIU 103, so that the system can communicate with an external network. The memory includes a system memory 108 and a mass storage device (MSD) 109; and the processor includes but is not limited to CPU. Further, the system also includes a system bus 107 for internal transmission in the system, and an input device 106 and an I/O controller 104 for input and output.

The above described are merely several examples of the present invention. Although the description is specific and detailed, it should not be construed as a limitation to the patent scope of the present invention. It should be pointed out that several variations and improvements may be made by those of ordinary skill in the art without departing from the concept of the present invention, but such variations and improvements should fall within the protection scope of the present invention. Therefore, the patent protection scope of the present invention should be subject to the appended claims.

1. A method for creating a knowledge representation model for a product, comprising the following steps:
capturing text data and image data;
mining customer requirements and market requirements from the text data, and classifying and systematically representing the customer requirements and market requirements in the form of a semantic network, to establish a requirement model;
mining product information from the text data and image data, functionally decomposing the product information, dividing a main function to be achieved into sub-functions needed to achieve the main function, to establish a function model;
defining a behavior of each part of the product to establish a behavior model, the behavior being composed of various indicators to be achieved by the product;
decomposing a structure of the product into various mechanisms and components, and representing relevant geometric information of each of the mechanisms and components together to establish a structure model, the relevant geometric information being geometric information, material information or manufacture information;
recording design iteration and evolution processes of the requirement model, function model, behavior model and structure model, and capturing knowledge and experience therein, to establish an evolution model;
wherein the requirement model, function model, behavior model, structure model and evolution model are displayed on a screen to receive selection, addition, modification, deletion or saving operations performed by a user; and
integrating the requirement model, function model, behavior model, structure model and evolution model to build a complete knowledge representation model of the product.

2. The method for creating a knowledge representation model according to claim 1, wherein the step of mining customer requirements and market requirements from the text data, and classifying and systematically representing the customer requirements and market requirements in the form of a semantic network, to establish a requirement model comprises: transforming scattered and abstract requirements into various functions to be achieved by the product, and systematically capturing and representing knowledge and experience formed in this process in the form of know-what, know-how and know-why.

3. The method for creating a knowledge representation model according to claim 1, wherein the step of defining a behavior of each part of the product to establish a behavior model, the behavior being composed of various indicators to be achieved by the product comprises: setting an optimal indicator of each sub-function, and comparing an actually achieved indicator with the optimal indicator to iteratively improve the product design until the actual indicator reaches or approximates the optimal indicator.

4. The method for creating a knowledge representation model according to claim 1, wherein the step of decomposing a structure of the product into various mechanisms and components, and representing relevant geometric information of each of the mechanisms and components together to establish a structure model, the relevant geometric information being geometric information, material information or manufacture information comprises: dividing the structure of the product into systems, subsystems, mechanisms and components according to the functions of the product, and capturing corresponding information in the smallest unit of components.

5. The method for creating a knowledge representation model according to claim 1, wherein the step of recording design iteration and evolution processes of the requirement model, function model, behavior model and structure model, and capturing knowledge and experience therein, to establish an evolution model comprises: capturing the evolution process of a design scheme based on the requirement, function, behavior and structure models.

6. A system for creating a knowledge representation model for a product, comprising a display, a communication device, a memory and a processor, wherein the memory is used to store data and a computer program; the processor is used to execute the computer program stored on the memory to implement the method for creating a knowledge representation model according to claim 1.

7. A system for creating a knowledge representation model for a product, comprising a display, a communication device, a memory and a processor, wherein the memory is used to store data and a computer program; the processor is used to execute the computer program stored on the memory to implement the method for creating a knowledge representation model according to claim 2.

8. A system for creating a knowledge representation model for a product, comprising a display, a communication device, a memory and a processor, wherein the memory is used to store data and a computer program; the processor is used to execute the computer program stored on the memory to implement the method for creating a knowledge representation model according to claim 3.

9. A system for creating a knowledge representation model for a product, comprising a display, a communication device, a memory and a processor, wherein the memory is used to store data and a computer program; the processor is used to execute the computer program stored on the memory to implement the method for creating a knowledge representation model according to claim 4.

10. A system for creating a knowledge representation model for a product, comprising a display, a communication device, a memory and a processor, wherein the memory is used to store data and a computer program; the processor is used to execute the computer program stored on the memory to implement the method for creating a knowledge representation model according to claim 5.
